(19) United States
(12) Patent Application Publication
(10) Pub. No.: US 2006/0268711 A1
(43) Pub. Date: Nov. 30, 2006

(54) Network selection terminal

(76) Inventors: Anil Kumar Doradla, Austin, TX (US); Rias Muhamed, Austin, TX (US)

Correspondence Address: MATTHEW E. BURR;LAKE AUSTIN MARINA, 2219 WESTLAKE DR, STE 200, AUSTIN, TX, 78746, US

(21) Appl. No.: 11/139,434

(22) Filed: May 27, 2005

(51) Int. Cl. G01R 31/08

(52) U.S. Cl. 370/235; 370/252

(57) ABSTRACT

A system enhances communication services delivered across multiple (homogeneous and heterogeneous) access network environments. A user terminal (via a software client) passively collects the performance related parameters of all available access networks while being connected to only one of those access networks (the “active network”). The collected information is communicated over the active network to a central server. The central server uses the information to enhance the overall service performance by using it for intelligent network selection, handoff, load-balancing, monitoring, and other purposes. Computer readable media contain instructions for a computer to perform functions within the system.

### FIELD OF THE INVENTION

The present invention relates to telecommunications networks, and in particular to methods, systems and devices for selecting an active communication network in a multi-mode environment.

### BACKGROUND OF THE INVENTION

The deployment of wireless and wireline multiple network access technologies has proliferated the number of terminals that support multiple access technologies. Just recently, single terminals that support GSM/GPRS and Wi-Fi have been introduced and are expected to be popular in the marketplace.

It has become very common for consumers to subscribe to services of multiple access technologies from the same service provider. For example, an SBC® customer may have cellular service from Cingular,® subscribe to DSL at home and have a subscription to use SBC's FreedomLink™ network at public hotspots. Until recently, network operators treated each of these services as stand-alone distinct services. They did not attempt to converge the services offered over these different access networks to provide a user experience that would, for example, provide a seamless transition from one network to another based on the availability of the best access network at any given time or location.

However, over the past couple of years, a combination of technological feasibility and market demands began to change the service paradigm. Operators now want to support convergence of services across multiple access technologies, particularly across disparate wireless access technologies.

The present invention relates to selecting the optimum network in a multiple access network environment. As used herein, the terms “optimum” or “preferred” and their various forms are intended to refer broadly to any network preferred or selected on the basis of weighing a variety of factors, including, for example, cost and carrier affiliation. That is, the terms do not necessarily mean that the selected network has some technical or performance superiority over the non-selected networks.

Conventional systems require multi-mode terminals (terminals supporting multiple access technologies) to connect to all the available networks and use the best one for actual voice or data transmission based on a set of selection criterion. Maintaining multiple connections is wasteful of resources of both network (e.g., IP address, authentication resources) and client (e.g., battery power).

Therefore, it is beneficial to make and maintain connectivity to only the chosen network at any given time, while simultaneously being aware of the available alternatives. The problem, then, is one of determining the availability and suitability for voice and/or data transmission of alternative access networks without actually making and maintaining a connection with each of them. The present invention provides a solution to this problem.

### BRIEF DESCRIPTION OF THE DRAWINGS

The present invention is further described in the detailed description that follows, by reference to the noted drawings, by way of non-limiting examples of embodiments of the present invention, in which reference numerals represent the same parts throughout the several views of the drawings, and in which:

FIG. 1 is a schematic block diagram of one exemplary embodiment of a network selection system of the present invention, depicting first active network A.

FIG. 2 is a schematic block diagram of the embodiment of FIG. 1, depicting second active network B.

### DETAILED DESCRIPTION OF THE INVENTION

In view of the foregoing, the present invention, through one or more of its various aspects, embodiments and/or specific features or sub-components, is thus intended to bring out one or more of the advantages that will be evident from the description. The present invention is described with frequent reference to wireless telecommunications networks. It is understood, however, that wireless is merely an example of a specific embodiment of the present invention, which is directed broadly to communications and data networks within the scope of the invention. The terminology, examples, drawings and embodiments, therefore, are not intended to limit the scope of the invention. As used herein, the term “communication” and its various forms include either or both voice and data communication.

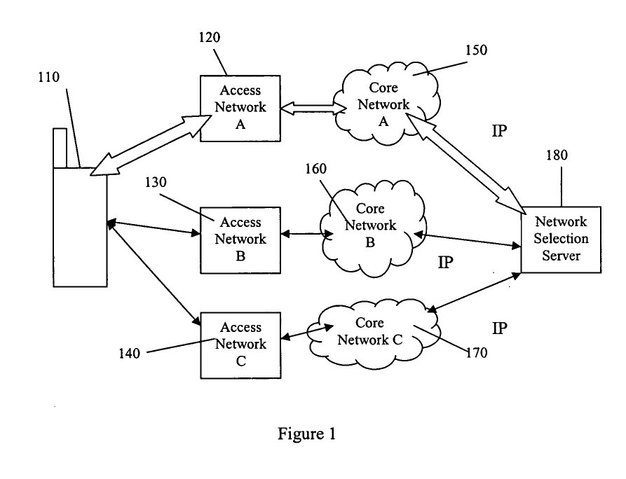

The invention is described by going through a user scenario and detailing the signaling processes involved. FIG. 1 is a schematic block diagram of one exemplary embodiment of a network selection system of the present invention, depicting first active network A. Terminal 110 possesses the capability of supporting multiple network technologies. Three access networks are denoted by Access Network A 120, B 130, and C 140. Terminal 110, also referred to as multi-mode terminal 110, supports access across multiple networks, multiple types of networks, and multiple network technologies. The different networks A, B and C each represent a different access network technology. For example, the terminal can connect to a Wi-Fi network, a cellular 3G network, and a Wi-Max network. Wi-Max is a standards-based wireless technology that provides high-throughput broadband connections over long distances. Wi-Max can be used for a number of applications, including “last mile” broadband connections, hotspots and cellular backhaul, and high-speed enterprise connectivity.

In FIG. 1, Network A is designated to be a Wi-Fi network, Network B a cellular 3G network and Network C a Wi-Max network for the purpose of describing the invention (although the drawing shows all the access networks to be wireless, the invention is extensible to wired networks as well. Wireless was chosen for illustration as it presents the more interesting user scenario.) Each of the access networks supports at least one common network layer protocol, such as Internet Protocol (IP) for example. Using IP as the shared network layer protocol makes specific embodiments of the present invention particularly well adapted for Voice over Internet Protocol (VoIP).

Accordingly, terminal 110 provides the hardware and client software to perform the network scanning and selection functions described below. Such hardware and software, it will be appreciated, are readily devised by those of ordinary skill in the art and the particular specifications of the technology may be chosen to suit whatever level of performance might be desired without the need to be set forth specifically herein.

1. A user with multi-mode terminal 110 is connected to Access Network A 120 which is a Wi-Fi telephone network. “Connected” means that the terminal is in a communicative association with the network, successfully completed the authentication process, and made a connection at the network layer using Internet Protocol. Access Network A 120 is the active network operating over Core Network A 150. Since terminal 110 is multi-mode in nature, it has the ability to connect to Network B 130 or C 140 (if these networks are available), but is currently only connected to A 150. The decision to connect to A was made locally by terminal 110 upon power-on, based on availability and a pre-determined priority order.

2. While terminal 110 is actively communicating through Network A, it periodically scans for the availability of Network B and Network C. The scanning function may be performed by any one of a number of means known to those skilled in the art. Scanning, or a scanner, is defined broadly herein to refer to any technology or set of technologies such that information is collected about the presence and characteristics of a network modality in a given location for which a multi-mode terminal of the present invention is enabled for communication. Accordingly, a scanner of the present invention may be, for example, software installed on the terminal that instructs each modality technology of the terminal to detect the presence of, and gather information about, the network modality of that technology.

The scanning means may be selected by terminal 110 on the basis of the capability of terminal 110 and type of networks available in the environment. The purpose of scanning is to find whether other networks are available in the geographical area where the terminal is located, and, if available, to determine the identity of each of the networks and the different network performance related parameters associated with each. For example:

Access Network B 130 is a cellular 3G network operating over Core Network B 160 and client device 110 supports Wi-Fi (including Wi-Max in specific embodiments). Terminal 110 determines the Access Point's (AP's) SSID (Network ID), BSSID (MAC Address), the data rate capabilities (e.g., 54, 11, 6, or 2 Mbps), the standard supported (e.g., 802.11a, b, g, n), the signal strength (RSSI), authentication and encryption schemes supported (e.g., WEP, WPA, AES, EAP, and the like.) and so forth.

Network C 140 is a cellular GSM/GPRS network operating over Core Network C 170 and client device 110 supports GSM/GPRS. Terminal 110 determines, via passive scanning of the BCCH channel of the base station, different parameters such as BSIC, MNC, RSSI, RXLev, RXQual and so forth.

There may be more than one Access Network of a particular type found by terminal 110. For example, the scan may show the presence of multiple Wi-Fi networks. In such case, data about all the available networks is gathered via passive scanning.

3. After collecting the data about all the available networks including the one to which terminal 110 is currently connected, the data is packaged to be sent over active Core Network A 150 via an IP connection to a Network Selection Server (NSS) 180. The packaging and organization of the data and the higher layer protocol used for communication between client terminal 110 and NSS 180 is appropriately chosen by terminal 110. For example, alternative embodiments communicate using TLS, HTTPS, or other proprietary protocols. Specific embodiments package the data in a pre-determined format to include all vital parameters in a particular order.

4. Once NSS 180 obtains the parameters from terminal 110, it processes the information to determine the optimal network for terminal 110 to connect to. NSS 180 determines the optimal, or preferred, network on the basis of, for example, a cost function that includes factors such as the type of access networks available in the environment, whether a particular network belongs to a preferred operator (such as a network operated by the provider of terminal 110) or to a roaming partner, the network throughput, signal strength, current loading conditions, application, and so forth.

5. Once NSS 180 selects a network based on the data provided by terminal 110, NSS 180 informs terminal 110 to prepare for handover to a particular network or to stay on the current active network.

Accordingly, the invention enables a client-assisted, network-controlled handover and network selection process without having to maintain multiple simultaneous network connections to terminal 110. The handover is accomplished by exchanging the data gathered about all the available networks over a single active network. The common protocol across the different networks, such as IP, enables the information exchange across a single active network.

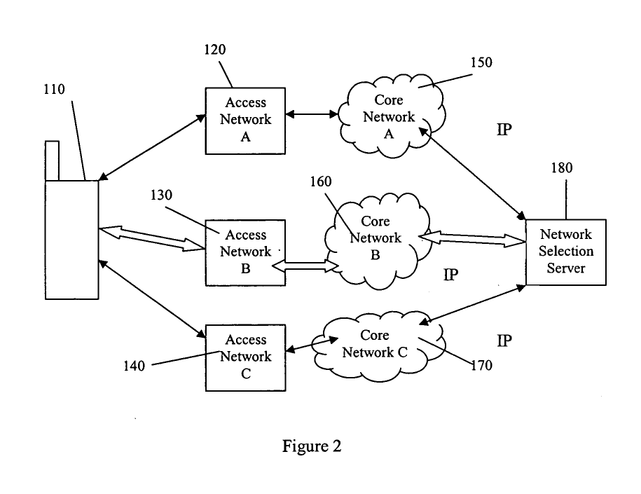

FIG. 2 is a schematic block diagram of the embodiment of FIG. 1, depicting second active network B. For example, terminal 110 is in a different network environment from that of FIG. 1, so that NSS 180 has selected Access Network B 130 operating via Core Network B 160 instead of Network A 150, and the handoff to Network B 160 has been successfully performed.

In accordance with various embodiments of the present invention, the methods described herein are intended for operation as software programs running on a computer processor. Dedicated hardware implementations including, but not limited to, application specific integrated circuits, programmable logic arrays and other hardware devices can likewise be constructed to implement the methods described herein. Furthermore, alternative software implementations including, but not limited to, distributed processing or component/object distributed processing, parallel processing, or virtual machine processing can also be constructed to implement the methods described herein.

It should also be noted that the software implementations of the present invention as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to e-mail or other self-contained information archive or set of archives is considered a distribution medium equivalent to a tangible storage medium. Accordingly, the invention is considered to include a tangible storage medium or distribution medium, as listed herein and including art-recognized equivalents and successor media, in which the software implementations herein are stored.

Although the present specification describes components and functions implemented in the embodiments with reference to particular standards and protocols, the invention is not limited to such standards and protocols. Each of the standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same functions are considered equivalents.

Those skilled in the art will recognize that the present invention extends to computer readable media (“CRM”) applications. CRM is broadly defined to include any kind of computer memory such as floppy disks, conventional hard disks, CD-ROMs, Flash ROMS, nonvolatile ROM, RAM, Storage Media, and Signals containing instructions, together with processors to execute the instructions. Accordingly, the present invention contemplates CRM containing a set of instructions, or that receives and executes instructions from a propagated signal, for the terminal to scan the network environment for the available networks, collect data about the available networks, transmit the collected data to a network selection server, and to automatically communicate over the network selected by the server.

Specific embodiments provide a terminal that houses the CRM. Similarly, embodiments of the network selection server of the invention house a computer-readable storage medium containing a set of instructions for selecting the preferred network for the terminal based on the collected and received data. The terminal automatically communicates over the selected network.

Specific embodiments provide a multi-mode telecommunications terminal that houses a CRM computer-readable storage medium containing a set of instructions, a scanner that scans a multi-network environment for available networks that share a communication protocol, a data collector that collects data obtained from the scanner, a transmitter or transceiver in communication with a network selection server to transmit the collected data to the selection server, and a network selection client that automatically hands off communications to the network selected by the network selection server. The CRM medium, or media, includes the instructions, or receives the instructions from a signal, for the terminal to perform the indicated functions.

Additionally, it will be understood that a terminal of the present invention includes broadly any electronic device that provides voice or data communication, such as a telephone, a cordless telephone, a mobile phone, a cellular telephone, a GSM cellular telephone, a Personal Digital Assistant (PDA), a BlackBerry®-type device, and a personal computer.

The invention has been described with reference to several exemplary embodiments. It is understood, however, that the words that have been used are words of description and illustration, rather than words of limitation. Changes may be made within the purview of the appended claims, as presently stated and as amended, without departing from the scope and spirit of the invention in all its aspects. Although the invention has been described with reference to particular means, materials and embodiments, the invention is not intended to be limited to the particulars disclosed; rather, the invention extends to all functionally equivalent technologies, structures, methods and uses such as are within the scope of the appended claims.

We claim:

1. A telecommunications system for the automatic selection of the preferred network in a multiple communications network environment, the system comprising:
at least two communications networks in the environment;
a network layer protocol shared by all the networks;
a network selection server connected to the networks using the shared protocol; and
a multi-mode terminal in communication with the selection server, wherein the terminal scans the network environment for the available networks, collects data on the available networks, transmits the collected data to the selection server, and communicates over the network selected by the server,
whereby the network selection server selects the preferred network for the terminal based on the collected data and the terminal automatically communicates over the selected network.

2. The system of claim 1, wherein the shared network layer protocol comprises Internet Protocol.

3. The system of claim 1, wherein at least one network is a wireless network.

4. The system of claim 1, wherein the terminal comprises a mobile telephone.

5. The system of claim 1, wherein at least one network supports VoIP.

6. The system of claim 1, wherein at least one network supports Wi-Fi.

7. The system of claim 1, wherein the terminal packages the collected data for transmission to the network selection server.

8. The system of claim 1, wherein at least one network comprises a cellular network.

9. The system of claim 8, wherein the cellular network further comprises a GSM network.

10. A method for communicating over a preferred network in a multi-network environment, the method comprising:
providing a network layer protocol shared by all the networks in the environment;
providing a network selection server connected to the networks by the shared protocol;
providing a multi-mode terminal in communication with the selection server;
scanning the environment for the available networks;
collecting data about the available networks;
transmitting the collected data to the selection server;
selecting the preferred network on the basis of the collected data; and
communicating with the terminal over the network selected by the server.

11. The method of claim 10, further comprising packaging the collected data for transmission to the network selection server.

12. The method of claim 10, wherein the shared network layer protocol comprises Internet Protocol.

13. The method of claim 10, wherein at least one network is a wireless network.

14. The method of claim 10, wherein the terminal comprises a mobile telephone.

15. The method of claim 10, wherein at least one network supports VoIP.

16. The method of claim 10, wherein at least one network supports Wi-Fi.

17. The method of claim 10, wherein at least one network comprises a cellular network.

18. The method of claim 17, wherein the cellular network further comprises a GSM network.

19. A multi-mode telecommunications terminal comprising:
a scanner that scans a multi-network environment for available networks that share a communication protocol;
a data collector that collects data obtained from the scanner;
a transmitter in communication with a network selection server to transmit the collected data to the selection server; and
a network selection client that automatically hands off communications to the network selected by the network selection server.

20. The terminal of claim 19, wherein the terminal comprises a mobile telephone.

21. The terminal of claim 19, further comprising a computer-readable medium containing one or more computer programs for operation of the terminal.

24. A multi-mode telecommunications terminal having one or more computer-readable media containing one or more computer programs for operation of the terminal, the terminal comprising:
a scanner that scans a multi-network environment for available networks that share a communication protocol;
a data collector that collects data obtained from the scanner;
a transmitter in communication with a network selection server to transmit the collected data to the selection server; and
a network selection client that automatically hands off communications to the network selected by the network selection server.

25. The terminal of claim 24, wherein the computer-readable medium receives one or more computer program from a signal.

27. The terminal of claim 24, wherein the terminal comprises one or more of the following: a wireless telephone, a PDA, a POTS telephone and a BlackBerry®-like device.

31. A computer readable medium containing instructions for execution by a computer, wherein the instructions instruct the terminal to:
scan the network environment for the available networks that share a network layer protocol,
collect data about the available networks;
transmit the collected data to a network selection server; and
automatically communicate over the network selected by the server.

32. A propagated signal containing the instructions for execution by a computer terminal, wherein the instructions instruct the terminal to:
scan the network environment for the available networks that share a network layer protocol,
collect data about the available networks;
transmit the collected data to a network selection server; and
automatically communicate over the network selected by the server.
